(19) United States
(12) Patent Application Publication
(10) Pub. No.: US 2025/0056969 A1
(43) Pub. Date: Feb. 13, 2025

(54) METHOD OF MANUFACTURING DISPLAY DEVICE

(71) Applicant: Samsung Display Co., Ltd., Yongin-si (KR)

(72) Inventors: Sungwoon Kim, Yongin-si (KR); Duckjung Lee, Yongin-si (KR)

(21) Appl. No.: 18/784,800

(22) Filed: Jul. 25, 2024

(30) Foreign Application Priority Data
Aug. 10, 2023 (KR) 10-2023-0105131

(51) Int. Cl. H10K 59/12; H10K 59/122; H10K 59/80

(52) U.S. Cl. CPC H10K 59/1201; H10K 59/122; H10K 59/8792

(57) ABSTRACT

In a method of manufacturing a display device, the method includes: positioning a substrate; forming a functional layer on the substrate; forming a mask including an opening in the functional layer; radiating pulse light including a plurality of pulses through the opening of the mask; and removing the functional layer to which the pulse light is radiated.

### CROSS-REFERENCE TO RELATED APPLICATION

The present application claims priority to and the benefit of Korean Patent Application No. 10-2023-0105131, filed on Aug. 10, 2023, in the Korean Intellectual Property Office, the entire disclosure of which is incorporated herein by reference.

### BACKGROUND

### 1. Field

Aspects of one or more embodiments relate to a method of manufacturing a display device.

### 2. Description of the Related Art

A display device visually displays data. A display device displays images using light emitting diodes. The use of display devices has become more diverse, and various designs have been attempted to improve the quality of display devices.

The above information disclosed in this Background section is only for enhancement of understanding of the background and therefore the information discussed in this Background section does not necessarily constitute prior art.

### SUMMARY

Aspects of one or more embodiments relate to a method of manufacturing a display device.

Additional aspects will be set forth in part in the description which follows and, in part, will be apparent from the description, or may be learned by practice of the presented embodiments of the disclosure.

According to some embodiments of the present disclosure, a method of manufacturing a display device includes: positioning a substrate, forming a functional layer on the substrate, forming a mask including an opening in the functional layer, radiating pulse light including a plurality of pulses through the opening of the mask, and removing the functional layer to which the pulse light is radiated.

According to some embodiments, the method may further include, after the positioning of the substrate, forming a pixel definition layer including plurality of openings in which a pixel electrode is located, on the substrate.

According to some embodiments, the mask may include a plurality of openings, and the mask may be formed such that the plurality of openings of the mask are positioned on a region in which the pixel definition layer is located.

According to some embodiments, the functional layer to which the pulse light is radiated may be at least a portion of a functional layer on the pixel definition layer.

According to some embodiments, the forming of the functional layer on the substrate may further include forming a lower functional layer on the pixel electrode and the pixel definition layer, and forming an upper functional layer on the lower functional layer.

According to some embodiments, the lower functional layer may include at least one of a hole injection layer or a hole transport layer.

According to some embodiments, the upper functional layer may include at least one of an electron injection layer or an electron transport layer.

According to some embodiments, the method may further include, between the forming of the lower functional layer and the forming of the upper functional layer, forming an emission layer in the opening of the pixel definition layer.

According to some embodiments, a size of the opening of the mask may be smaller than a size of the region in which the pixel definition layer is located.

According to some embodiments, the pulse light may be emitted from a flash lamp.

According to some embodiments, the pulse light may be light with a wavelength band of ultraviolet, visible, or infrared light.

According to some embodiments, the method may further include forming a light absorption layer on the pixel definition layer.

According to some embodiments, the light absorption layer may contact an upper surface of the pixel definition layer.

According to some embodiments, a size of the light absorption layer may be smaller than a size of the region in which the pixel definition layer is located.

According to some embodiments, the light absorption layer may include molybdenum (Mo) or aluminum (Al).

According to some embodiments, the method may further include discharging a residue of a removed portion of the functional layer through openings of a chamber in which the substrate is located.

According to some embodiments, the method may further include forming a deposit prevention plate below the mask.

According to some embodiments, the method may further include collecting and discharging a residue of a removed portion of the functional layer on the transparent deposit prevention plate.

According to some embodiments of the present disclosure, a method of manufacturing a display device includes positioning a substrate, forming a pixel definition layer including an opening in which a pixel electrode is located, on the substrate, forming a functional layer on the pixel electrode and the pixel definition layer, forming a mask including an opening such that the opening of the mask is positioned in a region in which the pixel definition layer is located, radiating light emitted from a flash lamp, through the opening of the mask, and removing a functional layer on the pixel definition layer to which the light emitted from the flash lamp is radiated.

According to some embodiments, the method may further include forming a light absorption layer to be in contact with an upper surface of the pixel definition layer.

### BRIEF DESCRIPTION OF THE DRAWINGS

The above and other aspects, features, and characteristics of certain embodiments of the present disclosure will be more apparent from the following description taken in conjunction with the accompanying drawings, in which:

FIG. 1 is a schematic plan view of a display device according to some embodiments;

FIGS. 2A and 2B are equivalent circuit diagrams of pixels, according to some embodiments;

FIGS. 3A and 3B are schematic cross-sectional views of a display device, according to some embodiments;

FIGS. 4A and 4B are cross-sectional views of a circuit device layer of a display device according to some embodiments; and

FIGS. 5A to 8B are schematic cross-sectional views illustrating a method of manufacturing a display device according to some embodiments.

### DETAILED DESCRIPTION

Reference will now be made in more detail to aspects of some embodiments, which are illustrated in the accompanying drawings, wherein like reference numerals refer to like elements throughout. In this regard, the present embodiments may have different forms and should not be construed as being limited to the descriptions set forth herein. Accordingly, the embodiments are merely described below, by referring to the figures, to explain aspects of the present description. As used herein, the term “and/or” includes any and all combinations of one or more of the associated listed items. Throughout the disclosure, the expression “at least one of a, b or c” indicates only a, only b, only c, both a and b, both a and c, both b and c, all of a, b, and c, or any combination of a, b, and/or c.

As the disclosure allows for various changes and numerous embodiments, particular embodiments will be illustrated in the drawings and described in detail in the written description. The attached drawings for illustrating embodiments are referred to gain a sufficient understanding of embodiments, the merits thereof, and the objectives accomplished by the implementation of the disclosure. However, the disclosure is not limited to the embodiments disclosed below, but may be implemented in various different forms.

Hereinafter, aspects of some embodiments of the present disclosure will be described in more detail by explaining one or more embodiments with reference to the attached drawings. The same reference numerals in the drawings denote like elements, and a repeated explanation thereof will not be given.

In the following embodiments, terms such as first and second are not limited by the terms and are used only for the purpose of distinguishing one component from another component.

In the following embodiments, the singular expressions in the present specification include the plural expressions unless clearly specified otherwise in context.

In the following embodiments, terms such as include or have represent that the features or elements described in the specification exist, and do not preclude the possibility that one or more other features or elements may be added.

In the following embodiments, when various components such as a film, a region, and a component are referred to as being above or on other components, this includes the case in which the components are directly on other components as well as the case in which other components are located therebetween.

For convenience of explanation, in the drawings, the size of components may be exaggerated or reduced. For example, the size and thickness of each component shown in the drawings are arbitrarily shown for convenience of description, and thus the disclosure is not necessarily limited to the drawings.

When an embodiment is otherwise embodied, a specific process order may be performed differently from the described order. For example, two processes described in succession may be performed substantially simultaneously (or concurrently), or may be performed in an order opposite to the order described.

In this specification, the expression “A and/or B” represents the case of A, B, or A and B. In addition, the expression “at least one of A and B” represents the case of A, B, or A and B.

In the following embodiments, when films, regions, components, and the like are described to be connected, this also includes cases in which the films, regions, and components are directly connected, and/or other films, regions, and components are located between films, regions, and components and are indirectly connected thereto. For example, in this specification, when films, regions, components, and the like are described to be connected electrically, this also includes cases in which the films, regions, and components are directly electrically connected and/or other films, regions, and components are located between films, regions, and components and are electrically and indirectly connected thereto.

The x-axis, y-axis, and z-axis are not limited to the three axes in the Cartesian coordinate system and may be interpreted in a broad sense including these. For example, the x-axis, y-axis, and z-axis may be orthogonal to each other, but may also refer to different directions that are not orthogonal to each other.

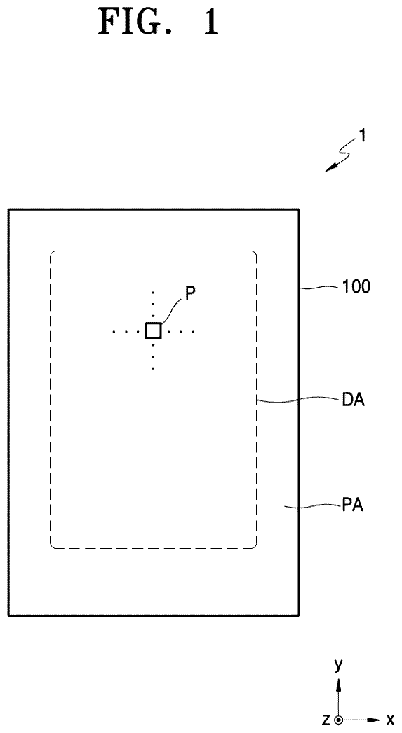

FIG. 1 is a schematic plan view of a display device 1 according to some embodiments.

Referring to FIG. 1, the display device 1 includes a display area DA and a peripheral area PA as a non-display area. Pixels P including an organic light-emitting device OLED are arranged in the display area DA to provide a certain image. The peripheral area PA is a region in which no image is provided, and includes a scan driver and a data driver that provide an electrical signal to be applied to the pixels P of the display area DA, and power lines that provide power such as a driving voltage and a common voltage.

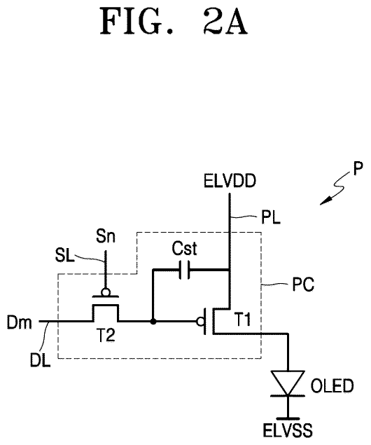

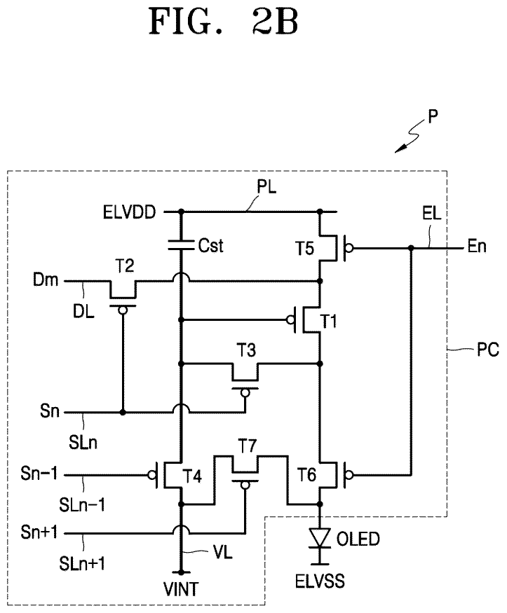

FIGS. 2A and 2B are equivalent circuit diagrams of pixels P, according to some embodiments.

Referring to FIG. 2A, each pixel P includes a pixel circuit PC connected to a scan line SL and a data line DL and an organic light-emitting device OLED connected to the pixel circuit PC.

The pixel circuit PC includes a driving thin film transistor T1, a switching thin film transistor T2, and a storage capacitor Cst. The switching thin film transistor T2 is connected to the scan line SL and the data line DL, and transfers a data signal Dm input through the data line DL according to a scan signal Sn input through the scan line SL to the driving thin film transistor T1.

The storage capacitor Cst is connected to the switching thin film transistor T2 and the driving voltage line PL, and stores a voltage corresponding to a difference between a voltage received from the switching thin film transistor T2 and a driving voltage ELVDD supplied to a driving voltage line PL.

The driving thin film transistor T1 may be connected to the driving voltage line PL and the storage capacitor Cst, and in response to a voltage value stored in the storage capacitor Cst, the driving thin film transistor T1 may control a driving current flowing in the organic light-emitting device OLED from the driving voltage line PL. The organic light-emitting device OLED may emit light having a certain brightness by a driving current.

In FIG. 2A, the pixel P includes two thin film transistors and one storage thin film transistor, but the disclosure is not limited thereto.

Referring to FIG. 2B, the pixel circuit PC may include the driving and switching thin film transistor T1 and T2, a compensation thin film transistor T3, a first initialization thin film transistor T4, a first light emitting control thin film transistor T5, a second light emitting control thin film transistor T6, and a second initialization thin film transistor T7.

A drain electrode of the driving thin film transistor T1 may be electrically connected to the organic light-emitting device OLED via the second light emitting control thin film transistor T6. The driving thin film transistor T1 receives a data signal Dm according to a switching operation of the switching thin film transistor T2 to supply a driving current to the organic light-emitting device OLED.

A gate electrode of the switching thin film transistor T2 is connected to a first scan line SLn, and a source electrode is connected to the data line DL. A drain electrode of the switching thin film transistor T2 is connected to a source electrode of the driving thin film transistor T1 and may be connected to the driving voltage line PL via the first light emitting control thin film transistor T5.

The switching thin film transistor T2 is turned on according to a first scan signal Sn received through the first scan line SLn to perform a switching operation of transferring the data signal Dm received through the data line DL to the source electrode of the driving thin film transistor T1.

A gate electrode of the compensation thin film transistor T3 may be connected to the first scan line SLn. A source electrode of the compensation thin film transistor T3 may be connected to the drain electrode of the driving thin film transistor T1 and may be connected to the pixel electrode of the organic light-emitting device OLED through the second light emitting control thin film transistor T6. A drain electrode of the compensation thin film transistor T3 may be connected to any one electrode of the storage capacitor Cst, a source electrode of the first initialization thin film transistor T4, and a gate electrode of the driving thin film transistor T1. The compensation thin film transistor T3 is turned on according to the first scan signal Sn received through the first scan line SLn to connect the gate electrode and drain electrode of the driving thin film transistor T1 to each other and achieve diode-connection on the driving thin film transistor T1.

A gate electrode of the first initialization thin film transistor T4 may be connected to a second scan line SLn−1. A drain electrode of the first initialization thin film transistor T4 may be connected to an initialization voltage line VL. The source electrode of the first initialization thin film transistor T4 may be connected to any one electrode of the storage capacitor Cst, the drain electrode of the compensation thin film transistor T3, and the gate electrode of the driving thin film transistor T1. The first initialization thin film transistor T4 may be turned on according to a second scan signal Sn−1 received through the second scan line SLn−1 to perform an initialization operation of transferring an initialization voltage VINT to the gate electrode of the driving thin film transistor T1 and initializing a voltage of the gate electrode of the driving thin film transistor T1.

A gate electrode of the first light emitting control thin film transistor T5 may be connected to a light emitting control line EL. A source electrode of the first light emitting control thin film transistor T5 may be connected to the driving voltage line PL. A drain electrode of the first light emitting control thin film transistor T5 is connected to the source electrode of the driving thin film transistor T1 and the drain electrode of the switching thin film transistor T2.

A gate electrode of the second light emitting control thin film transistor T6 may be connected to the light emitting control line EL. A source electrode of the second light emitting control thin film transistor T6 may be connected to the drain electrode of the driving thin film transistor T1 and the source electrode of the compensation thin film transistor T3. A drain electrode of the second light emitting control thin film transistor T6 may be electrically connected to the pixel electrode of the organic light-emitting device OLED. The first light emitting control thin film transistor T5 and the second light emitting control thin film transistor T6 are turned on at the same time according to a light emitting control signal En received through the light emitting control line EL to transfer the driving voltage ELVDD to the organic light-emitting device OLED and allow a driving current to flow in the organic light-emitting device OLED.

A gate electrode of the second initialization thin film transistor T7 may be connected to a third scan line SLn+1. A source electrode of the second initialization thin film transistor T7 may be connected to the pixel electrode of the organic light-emitting device OLED. A drain electrode of the second initialization thin film transistor T7 may be connected to the initialization voltage line VL. The second initialization thin film transistor T7 may be turned on according to the third scan signal Sn+1 received through the third scan line SLn+1 to initialize the pixel electrode of the organic light-emitting device OLED.

Another electrode of the storage capacitor Cst may be connected to the driving voltage line PL. Any one electrode of the storage capacitor Cst may be connected to the gate electrode of the driving thin film transistor T1, the drain electrode of the compensation thin film transistor T3, and the source electrode of the first initialization thin film transistor T4.

Counter electrodes of the organic light-emitting device OLED receive a common power voltage ELVSS. The organic light-emitting device OLED receives a driving current from the driving thin film transistor T1 to emit light.

The pixel circuit PC is not limited to the number and circuit design of the thin film transistor and storage capacitor described with reference to FIGS. 2A and 2B, and the number and circuit design may be changed in various ways.

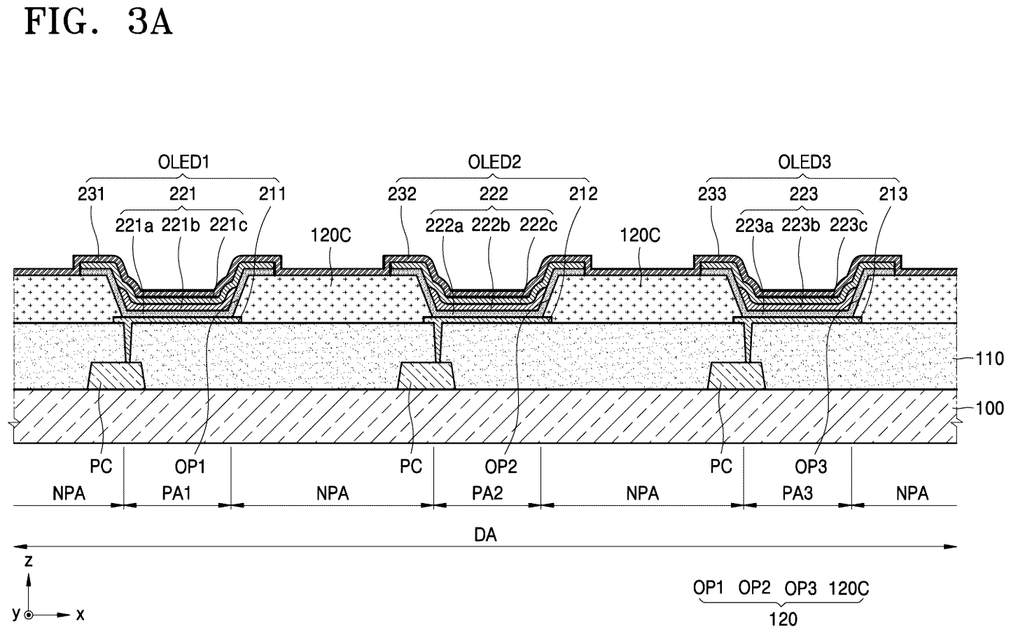

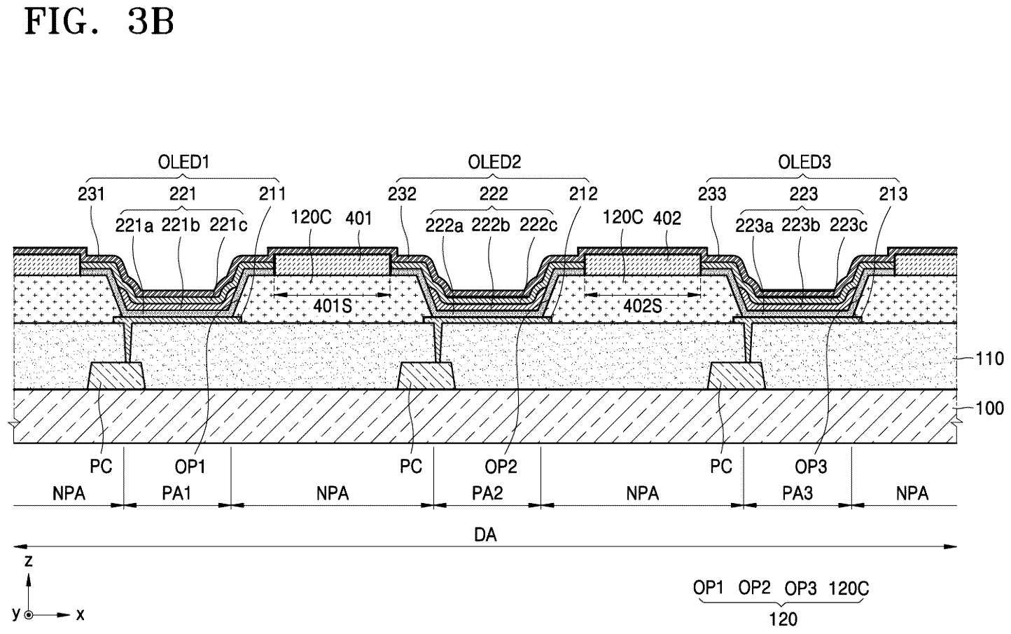

FIGS. 3A and 3B are schematic cross-sectional views of a display device, according to some embodiments.

Referring to FIG. 3A, the display area DA includes first to third pixel areas PA1, PA2, and PA3 in which organic light-emitting devices, for example, first to third organic light-emitting devices OLED1, OLED2, and OLED3 are arranged, and includes a non-pixel area NPA between neighboring pixel areas. The pixel area in the specification corresponds to a region in which light is actually emitted, that is, a light emitting region.

The first to third organic light-emitting devices OLED1, OLED2, and OLED3 may implement different colors. For example, the first organic light-emitting device OLED1 may implement red, the second organic light-emitting device OLED2 may implement green, and the third organic light-emitting device OLED3 may implement blue. According to some embodiments, the display area DA may further include a fourth organic light-emitting device that implements white.

To implement ultra-high definition, substrate 100 may include a semiconductor material such as group IV semiconductors, group Ill-V semiconductors or group II-VI semiconductors. The substrate 100 may include a silicone layer. That is, the substrate 100 may be a semiconductor substrate including a semiconductor material. According to some embodiments, the substrate 100 may be a C-MOS substrate. As such, an OLED display device using the substrate 100 containing a semiconductor material may be referred to as an OLED on silicon (OLEDoS). The OLEDoS may be used mainly for expansion reality (XR) and may implement ultra-high definition greater than or equal to 8 K in a small area of about 1 to about 2 inches. When a semiconductor substrate is used, dense control of pixels arranged with ultra-high definition may be possible. In a different expression, a semiconductor substrate may be used in the case of a micro display device having a length of about 2 μm to about 4 μm in a first direction (e.g., X or −X direction) of a pixel PX (refer to FIG. 1). However, the disclosure is not limited thereto.

The type of the substrate 100 may not be limited to a semiconductor substrate. For example, the substrate 100 may include glass, a metal or a polymer resin. In addition, the substrate 100 may include a polymer resin such as polyethersulfone, polyacrylate, polyetherimide, polyethylene naphthalate, polyethylene terephthalate, polyphenylene sulfide, polyarylate, polyimide, polycarbonate, or cellulose acetate propionate. The substrate 100 may be modified in various ways, and for example, may have a multilayer structure including two layers each containing such a polymer resin and a barrier layer located between the two layers and including an inorganic material (such as silicon oxide, silicon nitride, or silicon oxynitride).

A circuit device layer 110 including the pixel circuit PC is provided on the substrate 100. The pixel circuit PC includes the thin film transistor and the storage capacitor as described above with reference to FIGS. 2A and 2B. Layers constituting the thin film transistor and the storage capacitor, such as semiconductor layers and electrode layers, may be arranged with an insulating layer located therebetween. The pixel circuit PC is arranged at every first to third organic light-emitting devices OLED1, OLED2, and OLED3.

The first to third organic light-emitting devices OLED1, OLED2, and OLED3 each include a pixel electrode, an intermediate layer including an emission layer, and a counter electrode. The first to third organic light-emitting devices OLED1, OLED2, and OLED3 may be located in a first opening OP1, a second opening OP2, and a third opening OP3 of a pixel definition layer 120 to correspond thereto, respectively.

The first organic light-emitting device OLED1 includes a first pixel electrode 211, a first intermediate layer 221, and a first counter electrode 231. The second organic light-emitting device OLED2 includes a second pixel electrode 212, a second intermediate layer 222, and a second counter electrode 232. The third organic light-emitting device OLED3 includes a third pixel electrode 213, a third intermediate layer 223, and a third counter electrode 233.

Ends of the first to third pixel electrodes 211, 212, and 213 are each covered with the pixel definition layer 120, and central parts of the first to third pixel electrodes 211, 212, and 213 are exposed through the first opening OP1, the second opening OP2, and the third opening OP3 of the pixel definition layer 120, respectively, and are in contact with the first to third intermediate layers 221, 222 and 223 through the first opening OP1, the second opening OP2, and the third opening OP3 of the pixel definition layer 120, respectively.

That is, the pixel definition layer 120 includes a cover portion 120c that covers the ends of the first to third pixel electrodes 211, 212, and 213, and the first opening OP1, the second opening OP2, and the third opening OP3 through which the central parts of the first to third pixel electrodes 211, 212, and 213 are exposed, respectively.

The first to third intermediate layers 221, 222, and 223 each including an emission layer may be located in regions to which the first to third pixel electrodes 211, 212, and 213 are exposed by the pixel definition layer 120, the first to third counter electrodes 231, 232, and 233 may be located above the first to third intermediate layers 221, 222, and 223, respectively, and light may be emitted from an intermediate layer between the pixel electrode and the counter electrode, and accordingly, a pixel area is defined by the pixel definition layer 120.

The pixel definition layer 120 may be made of an organic or inorganic material. When the pixel definition layer is made of an organic material, the pixel definition layer 120 may include one or more organic insulation material selected from the group consisting of polyimide, polyamide, an acrylic resin layer, benzocyclobutene, and a phenol resin layer. When the pixel definition layer 120 is made of an inorganic material, the pixel definition layer 120 may be formed as a single layer or a multilayer including a silicon oxide (SiOx), a nitride silicon (SiNx), and/or a silicon oxynitride (SiON).

The first to third pixel electrodes 211, 212, and 213 may be island types arranged to correspond to the first to third pixel areas PA1, PA2, and PA3, respectively, and may be spaced apart from each other on the circuit device layer 110.

The first to third pixel electrodes 211, 212, and 213 may each be a reflective electrode or a transmissive electrode.

When the first to third pixel electrodes 211, 212, and 213 are each a reflective electrode, the first to third pixel electrodes 211, 212, and 213 may include a reflective film made of silver (Ag), magnesium (Mg), aluminum (Al), platinum (Pt), palladium (Pd), gold (Au), nickel (Ni), neodymium (Nd), iridium (Ir), chromium (Cr) or a compound thereof. Alternatively, the first to third pixel electrodes 211, 212, and 213 may include the aforementioned reflective film, and a transparent conductive oxide (TCO) film above and/or below the aforementioned reflective film. According to some embodiments, the first to third pixel electrodes 211, 212, and 213 may include three layers of ITO/Ag/ITO.

When the first to third pixel electrodes 211, 212, and 213 are each a transmissive electrode, the first to third pixel electrodes 211, 212, and 213 may be a transparent conductive oxide (TCO) layer. Alternatively, the first to third pixel electrodes 211, 212, and 213 may be a metal thin film including silver (Ag) or a silver (Ag) alloy, or a multilayer of a transparent conductive oxide layer formed on the aforementioned metal thin film.

The first to third intermediate layers 221, 222 and 223 may be island types arranged to correspond to the first to third pixel areas PA1, PA2, and PA3, respectively and may be spaced apart from each other. The first to third intermediate layers 221, 222 and 223 are located on the first to third pixel electrodes 211, 212, and 213 through the first opening OP1, the second opening OP2, and the third opening OP3 of the pixel definition layer 120, respectively.

Referring to FIGS. 3A and 3B, the first intermediate layer 221 may be located on the first pixel electrode 211 located in the first opening OP1 of the pixel definition layer 120. The second intermediate layer 222 may be located on the second pixel electrode 212 located in the second opening OP2 of the pixel definition layer 120. The third intermediate layer 223 may be located on the third pixel electrode 213 located in the third opening OP3 of the pixel definition layer 120. The first intermediate layer 221 includes a first emission layer 221b. The first emission layer 221b may be an organic emission layer that emits, for example, red light. The second intermediate layer 222 includes a second emission layer 222b. The second emission layer 222b may be an organic emission layer that emits, for example, green light. The third intermediate layer 223 includes a third emission layer 223b. The third emission layer 223b may be an organic emission layer that emits, for example, blue light.

The first intermediate layer 221 may further include a first lower functional layer 221a located below the first emission layer 221b and/or a first upper functional layer 221c located above the first emission layer 221b. The second intermediate layer 222 may further include a second lower functional layer 222a located below the second emission layer 222b and/or a second upper functional layer 222c located above the second emission layer 222b. The third intermediate layer 223 may further include a third lower functional layer 223a located below the third emission layer 223b and/or a third upper functional layer 223c located above the third emission layer 223b.

The first to third lower functional layers 221a, 222a, and 223a may each include a hole injection layer (HIL) and/or a hole transport layer (HTL). The first to third upper functional layers 221c, 222c, and 223c may each include an electron transport layer (ETL) and/or an electron injection layer (EIL). The first to third lower functional layers 221a, 222a, and 223a and/or the first to third upper functional layers 221c, 222c, and 223c may adjust an energy level of an emission layer to a pixel electrode or a counter electrode to help the emission layer effectively emit light.

The emission layer may be formed using various known light emitting materials, which may be formed using a known host and dopant. In the case of the dopant, both a known fluorescent dopant and a known phosphorus dopant may be used.

For example, the host may be 4,4′-N,N′-dicarbazole-biphenyl (Alq3C CBP), 9,10-di(naphthalen-2-yl)anthracene (ADN), distyrylarylene (DSA), or the like, but is not limited thereto.

A hole injection layer material may be a known hole injection material, for example, a phthalocyanine compound such as copper phthalocyanine, 4,4′,4″-tris (3-methylphenylphenylamino) triphenylamine (m-MTDATA), N,N′-di(1-naphthyl)-N,N′-diphenylbenzidine (NPB), TDATA, 2-TNATA, polyaniline/dodecylbenzenesulfonic acid (pani/DBSA), poly(3,4-ethylenedioxythiophene)/poly(4-styrenesulfonate) (PEDOT/PSS), polyaniline/camphor sulfonicacid (Pani/CSA), or polyaniline/poly(4-styrenesulfonate) (PANI/PSS), but is not limited thereto.

A hole transport material may be a known hole transport layer material, for example, a carbazole derivative such as N-phenylcarbazole and polyvinylcarbazole, or an amine derivative having an aromatic condensed ring, such as NPB, N,N′-bis(3-methylphenyl)-N,N′-diphenyl-[1,1-biphenyl]-4,4′-diamine (TPD), and N,N′-di(naphthalen-1-yl)-N,N′-diphenyl benzidine (α-NPD).

An electron transport layer material may be arbitrarily selected from known electron transport layer forming materials. For example, the electron transport layer material may be known materials such as a quinoline derivative, in particular, tris(8-quinolinolate) aluminum (Alq3), TAZ, or Balq, but is not limited thereto.

The electronic injection layer may be any material known as an electronic injection layer forming material such as LiF, NaClC CsF, Li₂O, or BaO.

The first to third lower functional layers 221a, 222a, and 223a, and the first to third upper functional layers 221c, 222c, and 223c may be formed in a single-layer structure or a multilayer structure, and the first to third lower functional layers 221a, 222a, and 223a, and the first to third upper functional layers 221c, 222c, and 223c may be omitted.

The first to third counter electrodes 231, 232, and 233 may be island types arranged to correspond to the first to third pixel areas PA1, PA2, and PA3, and may be spaced apart from each other. The first to third counter electrodes 231, 232, and 233 may be located on the first to third intermediate layers 221, 222 and 223, respectively.

The first to third counter electrodes 231, 232, and 233 may be a fluorescent electrode or a reflective electrode. The first to third counter electrodes 231, 232, and 233 may include at least one material of silver (Ag), magnesium (Mg), aluminum (AI), ytterbium (Yb), calcium (Ca), lithium (Li), and gold (Au). For example, the first to third counter electrodes 231, 232, and 233 may have a single layer or multiplayer including at least one of silver (Ag), magnesium (Mg), aluminum (AI), ytterbium (Yb), calcium (Ca), lithium fluoride/calcium (LiF/Ca), lithium fluoride/aluminum (LiF/AI), aluminum (AI), or gold (Au). In some embodiments, the first to third counter electrodes 231, 232, and 233 may each include a transparent conductive oxide (TCO) film. According to some embodiments, the first to third counter electrodes 231, 232, and 233 may each include a metal thin film including silver (Ag) and magnesium (Mg), and the amount of silver (Ag) may be greater than the amount of magnesium (Mg). According to some embodiments, the first to third counter electrodes 231, 232, and 233 may be provided in a multilayer structure of ytterbium/silver (Yb/Ag): magnesium/indium tin oxide (Mg/ITO).

Referring to FIG. 3B, a first light absorption layer 401 and a second light absorption layer 402 may be located on the pixel definition layer 120. In detail, the first light absorption layer 401 and the second light absorption layer 402 may be located on a cover portion 120c of the pixel definition layer 120. In another expression, the first light absorption layer 401 may be located between the first opening OP1 and the second opening OP2 of the pixel definition layer 120. In another expression, the first light absorption layer 401 may be located between the first organic light-emitting device OLED1 and the second organic light-emitting device OLED2. The second light absorption layer 402 may be located between the second opening OP2 and the third opening OP3 of the pixel definition layer 120. In another expression, the second light absorption layer 402 may be located between the second organic light-emitting device OLED2 and the third organic light-emitting device OLED3.

The first light absorption layer 401 and the second light absorption layer 402 may contact an upper surface of the pixel definition layer 120. The size of each of the first light absorption layer 401 and the second light absorption layer 402 may be smaller than the size of a region of the cover portion 120c of the pixel definition layer 120 (or a region in which the pixel definition layer 120 is located). The region of the cover portion 120c of the pixel definition layer 120 corresponds to the non-pixel area NPA, and thus the size of each of the first light absorption layer 401 and the second light absorption layer 402 may be smaller than the size of the non-pixel area NPA. The first light absorption layer 401 and the second light absorption layer 402 may each include molybdenum (Mo) or aluminum (AI).

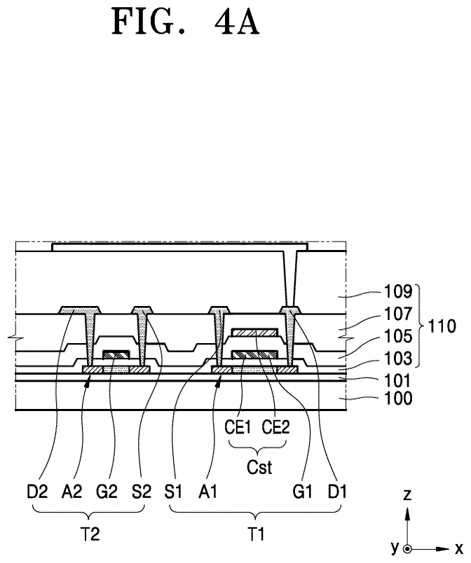

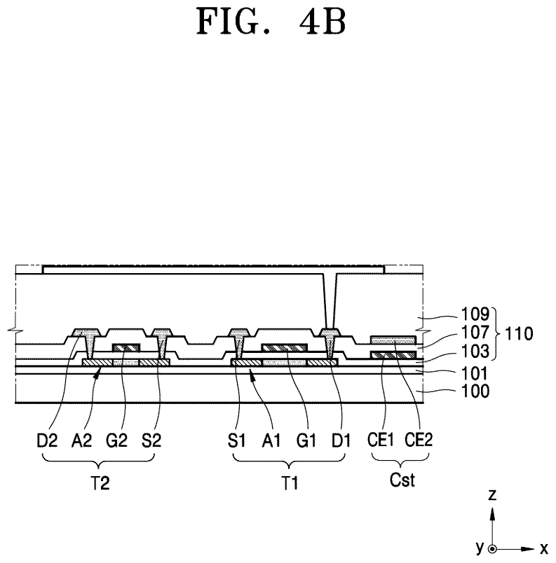

FIGS. 4A and 4B are cross-sectional views of a circuit device layer of a display device according to some embodiments.

Referring to FIG. 4A, the driving thin film transistor T1 may include a driving semiconductor layer A1, a driving gate electrode G1, a driving source electrode S1, and a driving drain electrode D1, the switching thin film transistor T2 may include a switching semiconductor layer A2, a switching gate electrode G2, a switching source electrode S2, and a switching drain electrode D2, and the storage capacitor Cst may include first and second storage capacitors CE1 and CE2.

A gate insulating layer 103 may be located between the driving and switching semiconductor layers A1 and A2 and the driving and switching gate electrodes G1 and G2, a dielectric layer 105 may be located between the first and second storage capacitors CE1 and CE2, an interlayer insulating layer 107 may be located between the driving and switching gate electrodes G1 and G2 and the driving and switching source/drain electrodes S1, D1, S2, and D2, and a planarization insulating layer 109 may be located on the driving and switching source/drain electrodes S1, D1, S2, and D2.

The gate insulating layer 103 may be a single layer or multilayer including an inorganic material such as a silicon nitride (SiNx) and/or a silicon oxide (SiOx). The dielectric layer 105 and the interlayer insulating layer 107 may be a single layer or multilayer including the aforementioned inorganic material such as a silicon oxide (SiOx), a silicon nitride (SiNx), and/or aluminum oxide (Al₂O₃). The planarization insulating layer 109 may include an organic material including a general-purpose polymer such as polymethylmethacrylate (PMMA) or polystylene (PS), a polymer derivative having a phenol-based group, acrylic polymer, imide-based polymer, aryl ether polymer, amide-based polymer, fluoride polymer, P-xylene-based polymer, vinyl alcohol-based polymer, and blend thereof, but the disclosure is not limited thereto.

FIG. 4A shows the case in which the storage capacitor Cst overlaps with the driving and switching thin film transistor T1 and T2 and the driving gate electrode G1 is the first storage capacitor CE1, but the disclosure is not limited thereto.

Referring to FIG. 4B, the storage capacitor Cst may be placed not to overlap with the driving thin film transistor T1. For example, the first storage capacitor CE1 and the driving gate electrode G1 may include the same material, the second storage capacitor CE2 may include the same material as the driving source and drain electrodes S1 and D1, and the interlayer insulating layer 107 may be located between the first and second storage capacitors CE1 and CE2.

According to the embodiments described with reference to FIGS. 4A and 4B, although the case in which the driving and switching gate electrodes G1 and G2 of the driving and switching thin film transistors T1 and T2 are located above the driving and switching semiconductor layers A1 and A2 is described, the disclosure is not limited thereto. According to some embodiments, the driving and switching gate electrodes G1 and G2 may be located below the driving and switching semiconductor layers A1 and A2, respectively. Depending on the locations of the driving and switching gate electrodes G1 and G2, in some embodiments, the driving and switching semiconductor layers A1 and A2 may be located directly above an inorganic buffer layer 101, and in some embodiments, the driving and switching gate electrodes G1 and G2 may be located directly above the inorganic buffer layer 101.

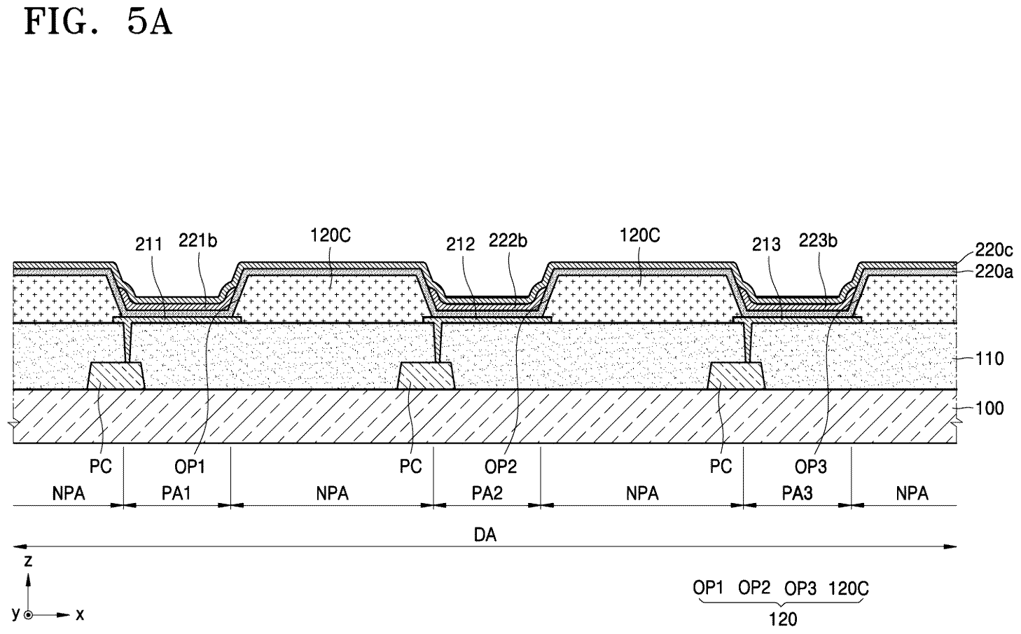

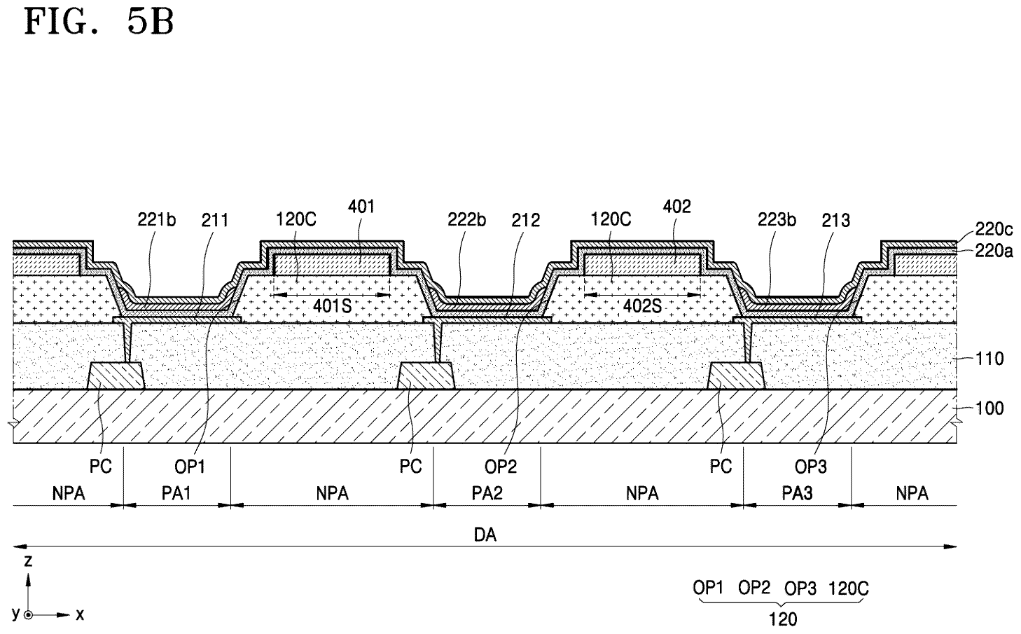

FIGS. 5A to 8B are schematic cross-sectional views of a method of manufacturing a display device according to some embodiments.

Referring to FIGS. 5A to 8B, the method of manufacturing the display device may include positioning the substrate 100, forming a lower functional layer 220a and an upper functional layer 220c on the substrate 100, forming a mask 500 including mask openings 5010P and 5020P on the lower functional layer 220a and the upper functional layer 220c, radiating pulse light 600 including a plurality of pulses through the mask openings 501OP and 5020P of the mask 500, and removing the lower functional layer 220a and the upper functional layer 220c to which the pulse light 600 is radiated.

Referring to FIGS. 5A and 5B, the method of manufacturing the display device may include, after the positioning of the substrate 100, forming the pixel definition layer 120 including a plurality of openings OP1, OP2, and OP3 in which pixel electrodes 211, 212, and 213 are located, on the substrate 100. In detail, the method of manufacturing the display device may include forming the pixel definition layer 120 including the first opening OP1 in which the first pixel electrode 211 is located, the second opening OP2 in which the second pixel electrode 212 is located, and the third opening OP3 in which the third pixel electrode 213 is located.

The forming of the functional layers 220a and 220c on the substrate 100 may include forming the lower functional layer 220a on the substrate 100 and forming the upper functional layer 220C on the lower functional layer 220a. The upper functional layer 220c and the lower functional layer 220a may be arranged continuously on the substrate 100. The lower functional layer 220a may include at least one of a HIL or a HTL. The upper functional layer 220c may include at least one of an EIL or an ETL.

The method of manufacturing the display device may include, between the forming of the lower functional layer 220a on the substrate 100 and the forming of the upper functional layer 220c on the substrate 100, forming the first emission layer 221b, the second emission layer 222b, and the third emission layer 223b on the substrate 100. The first emission layer 221b may emit red light, the second emission layer 222b may emit green light, and the third emission layer 223b may emit blue light. The first emission layer 221b may be arranged to correspond to the first opening OP1 of the pixel definition layer 120, the second emission layer 222b may be arranged to correspond to the second opening OP2 of the pixel definition layer 120, and the third emission layer 223b may be arranged to correspond to the third opening OP3 of the pixel definition layer 120.

As shown in FIG. 5B, unlike FIG. 5A, the method of manufacturing the display device may further include forming the first light absorption layer 401 and the second light absorption layer 402 on the pixel definition layer 120. The first light absorption layer 401 and the second light absorption layer 402 may be located on the cover portion 120c (the region in which the pixel definition layer 120 is located) of the pixel definition layer 120. The first light absorption layer 401 may be located between the first opening OP1 and the second opening OP2 of the pixel definition layer 120, and the second light absorption layer 402 may be located between the second opening OP2 and the third opening OP3 of the pixel definition layer 120. A size 401S of the first light absorption layer 401 and a size 402S of the second light absorption layer 402 may be equal to or smaller than a size of a region of the cover portion 120c of the pixel definition layer 120 (or the region in which the pixel definition layer 120 is located or the non-pixel area NPA).

The first light absorption layer 401 and the second light absorption layer 402 may include molybdenum (Mo) or aluminum (AI). The first light absorption layer 401 and the second light absorption layer 402 may be arranged to be in contact with an upper surface of the pixel definition layer 120. The lower functional layer 220a and the upper functional layer 220c may be arranged continuously on the first light absorption layer 401 and the second light absorption layer 402.

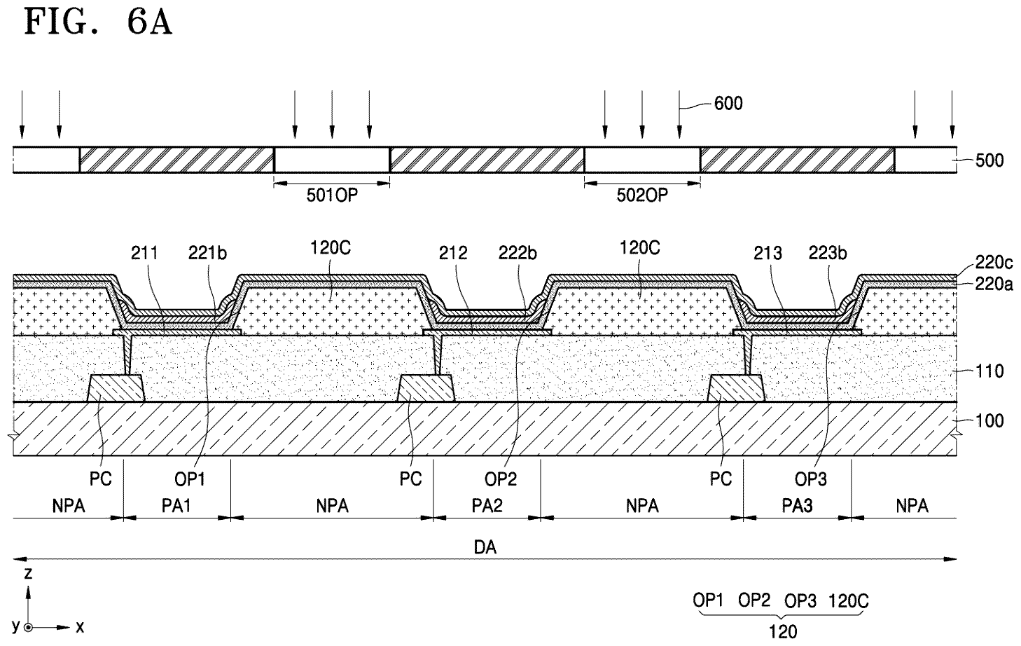

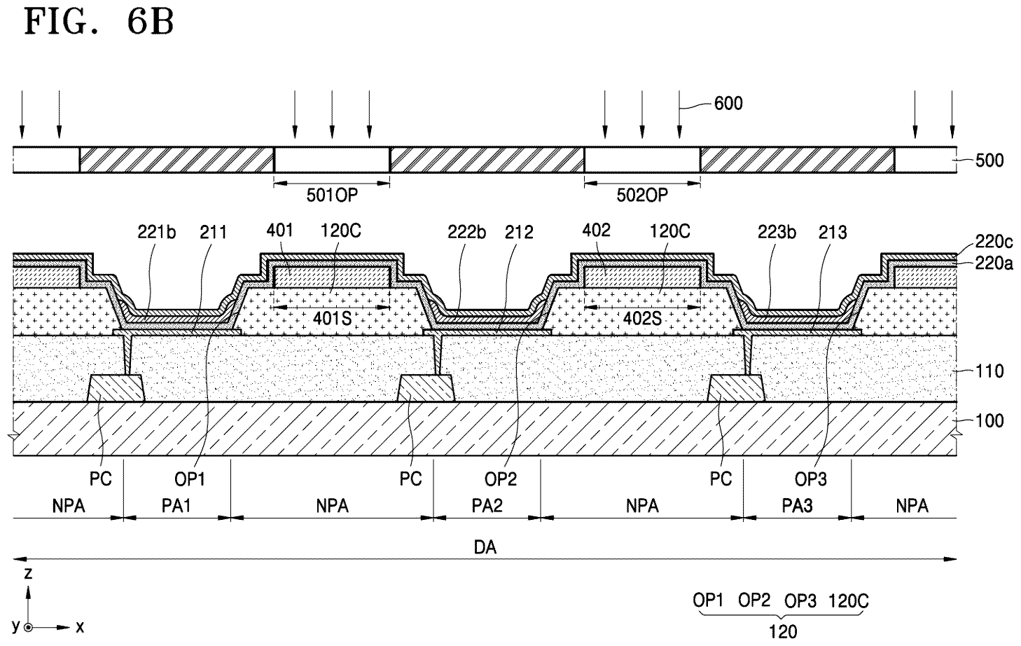

Referring to FIGS. 6A and 6B, the mask 500 may be located on the substrate 100 on which the lower functional layer 220a and the upper function layer 220c are located. The mask 500 may include a plurality of mask openings 501OP and 502OP.

The mask 500 may be arranged such that the plurality of mask openings 501OP and 502OP of the mask 500 are located on the region of the cover portion 120c of the pixel definition layer 120 (the region in which the pixel definition layer 120 is located or the non-pixel area NPA). In another expression, the mask 500 may be arranged such that the plurality of mask openings 501OP and 502OP of the mask 500 are aligned on the region of the cover portion 120c of the pixel definition layer 120 (the region in which the pixel definition layer 120 is located or the non-pixel area NPA). In detail, the mask 500 may be arranged such that a first mask opening 501OP is located on the cover portion 120c of the pixel definition layer 120 (the region in which the pixel definition layer 120 is located or the non-pixel area NPA) located between the first opening OP1 and the second opening OP2 of the pixel definition layer 120. The mask 500 may be arranged such that a second mask opening 502OP is located on the cover portion 120c of the pixel definition layer 120 (the region in which the pixel definition layer 120 is located or the non-pixel area NPA) located between the second opening OP2 and the third opening OP3 of the pixel definition layer 120.

The pulse light 600 including a plurality of pulses may be radiated through the mask openings 501OP and 502OP of the mask 500. A flash lamp may emit the pulse light 600 including a plurality of pulses, and radiate the pulse light 600 onto at least a portion of the functional layers 220a and 220c located on the region of the cover portion 120c of the pixel definition layer 120 (the region in which the pixel definition layer 120 is located or the non-pixel area NPA) through the mask openings 501OP and 502OP of the mask 500. In detail, through the first mask opening 501OP of the mask 500, pulse light may be radiated onto the lower functional layer 220a and the upper functional layer 220c located on the region of the cover portion 120c of the pixel definition layer 120 located between the first opening OP1 and the second opening OP2. Through the second mask opening 502OP of the mask 500, the pulse light 600 may be radiated onto the lower functional layer 220a and the upper functional layer 220c located on the region of the cover portion 120c of the pixel definition layer 120 located between the second opening OP2 and the third opening OP3.

The pulse light 600 may be light with a wavelength band of ultraviolet, visible, or infrared light. An interval between pulses of the pulse light 60 emitted from the flash lamp or the intensity of the pulse light may be adjusted.

Side leakage current may be generated in the functional layers 220a and 220c located on the cover portion 120c of the pixel definition layer 120. At least a portion of the functional layers 220a and 220c located on the cover portion 120c of the pixel definition layer 120 may be removed to prevent or reduce side leakage current flowing to the functional layers 220a and 220c located on the cover portion 120c of the pixel definition layer 120, thereby improving the reliability of the display device.

At least a portion of the functional layers 220a and 220c located on the region of the cover portion 120c of the pixel definition layer 120 (the region in which the pixel definition layer 120 is located or the non-pixel area NPA) to which the pulse light 600 is radiated through the mask openings 501OP and 502OP of the mask 500 may be removed using a photonic curing method. In detail, at least a portion of the functional layers 220a and 220c located on the region of the cover portion 120c of the pixel definition layer 120 (the region in which the pixel definition layer 120 is located or the non-pixel area NPA) between the first opening OP1 and the second opening OP2 to which the pulse light 600 is radiated through the first mask opening 501OP of the mask 500 may be removed using a photonic curing method. At least a portion of the functional layers 220a and 220c located on the region of the cover portion 120c of the pixel definition layer 120 (the region in which the pixel definition layer 120 is located or the non-pixel area NPA) between the second opening 502OP and the third opening OP3 to which the pulse light 600 is radiated through the second mask opening 502OP of the mask 500 may be removed using a photonic curing method. When the pulse light 600 is radiated to at least a portion of the functional layers 220a and 220c through the mask openings 501OP and 502OP of the mask 500, at least a portion of the functional layers 220a and 220c to which the pulse light 600 is radiated may be transiently heated and may be removed using a photonic curing method. According to the photonic curing method, at least a portion of the functional layers 220a and 220c located on the pixel definition layer may be removed without damage to the display device.

At least a portion of the functional layers 20a and 220c located on the cover portion 120c of the pixel definition layer 120 may be removed to prevent or reduce side leakage current, and thus the size of one mask opening 501OP or 502OP of the mask 500 may be smaller than the size of the region of the cover portion 120c of the pixel definition layer 120 (the region in which the pixel definition layer 120 is located or the non-pixel area NPA).

According to the related art, a functional layer adjacent to an electrode line may be removed using a Joule heating method by forming the electrode line on a pixel definition layer and applying a pulse voltage to the electrode line. When the electrode line is placed and the pulse voltage is applied to the electrode line, it may be difficult to apply a uniform pulse voltage on a front surface of a panel and ensure a regular heating technology.

When at least a portion of the functional layers 220a and 220c may be removed using a photonic curing method by radiating the pulse light 600 to at least a portion of the functional layers 220a and 220c located on the cover portion 120c of the pixel definition layer 120 through the mask openings 501OP and 502OP of the mask 500, an electrode line for applying a pulse voltage or a technology for controlling regular heating is not required, and thus the efficiency in manufacturing processes of the display device may be increased. Light emitted from a flash lamp may be radiated through the mask openings 501OP and 502OP of the mask 500, and thus a time required for the manufacturing processes of the display device may be reduced.

Referring to FIG. 6B, the first light absorption layer 401 and the second light absorption layer 402 may be located on the cover portion 120c of the pixel definition layer 120. The pulse light 600 may be radiated to the light absorption layers 401 and 402 located on the cover portion 120c of the pixel definition layer 120 through the mask openings 501OP and 502OP of the mask 500. The first light absorption layer 401 and the second light absorption layer 402 may include molybdenum (Mo) or aluminum (AI). The light absorption layers 401 and 402 may absorb the pulse light 600, and thus a degree of local heating or transient heating of at least a portion of the functional layers 220a and 220c located on the cover portion 120c of the pixel definition layer 120 around the light absorption layers 401 and 402 may be improved, and at least a portion of the functional layers 220a and 220c located on the cover portion 120c of the pixel crystal film 120 may be removed efficiently.

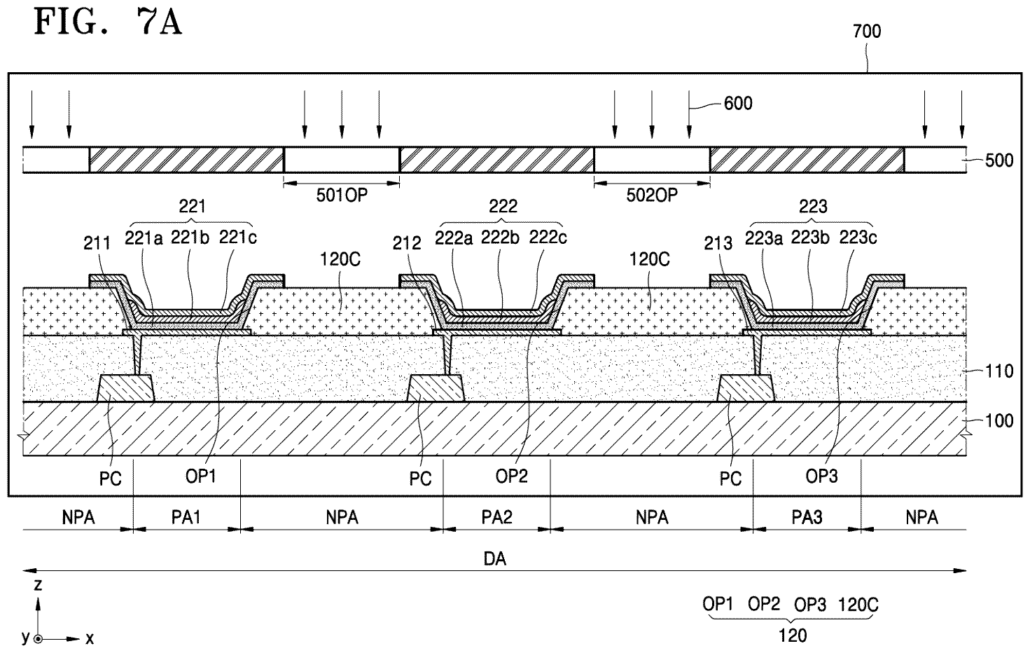

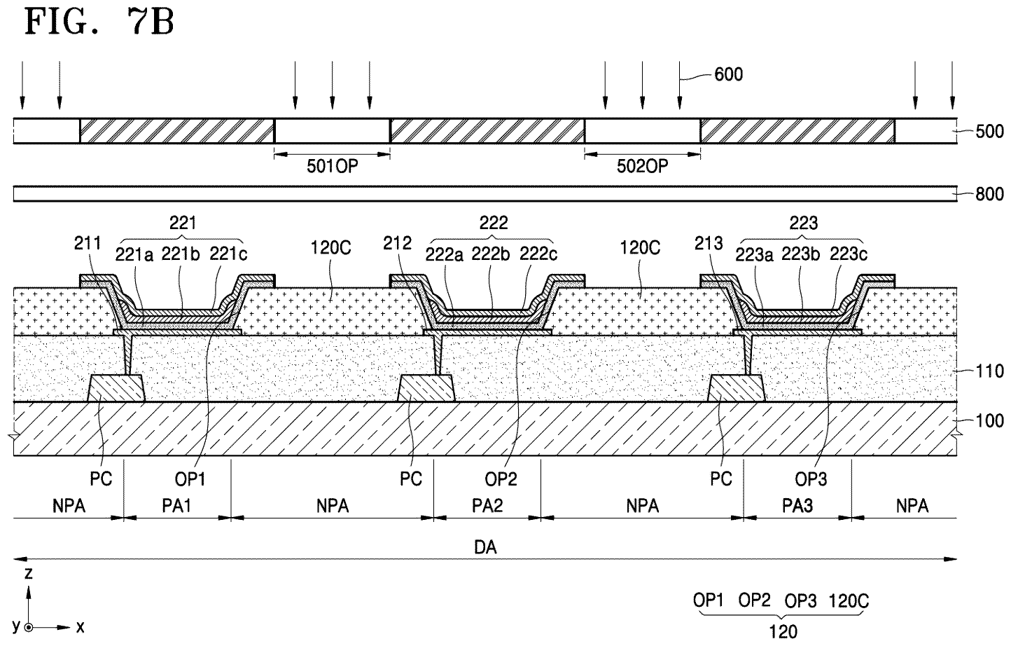

Referring to FIG. 7A, the method of manufacturing the display device may further include discharging a residue of at least the removed portion of the functional layer through openings of a chamber 700 in which the substrate 100 is located. The substrate 100 may be located in the chamber 700 and light may be radiated through the mask openings 501OP and 5020P of the mask 500. The chambers 700 in which the substrate 100 is located may include an opening, and residues of at least the portion of the functional layer, which is removed by radiating the pulse light 600, may be discharged through the openings of the chamber 700.

Referring to FIG. 7B, the method of manufacturing the display apparatus may further include forming a deposit prevention plate 800 below the mask 500, and collecting and discharging the residues of at least the removed portion of the functional layers 220a and 220c on the transparent deposit prevention plate 800. Differently from FIG. 7A, the transparent deposit prevention plate 800 may be located below the mask 500. The pulse light 600 radiated through the mask openings 501OP and 5020P of the mask 500 may pass through the transparent deposit prevention plate 800 located below the mask 500. At least the portion of the residues of the functional layers 220a and 220c, which is removed by radiating the pulse light 600, may be collected and discharged on the transparent deposit prevention plate 800. The transparent deposit prevention plate 800 may include a material to be reused by cleaning the residues of at least a portion of the attached functional layers 220a and 220c.

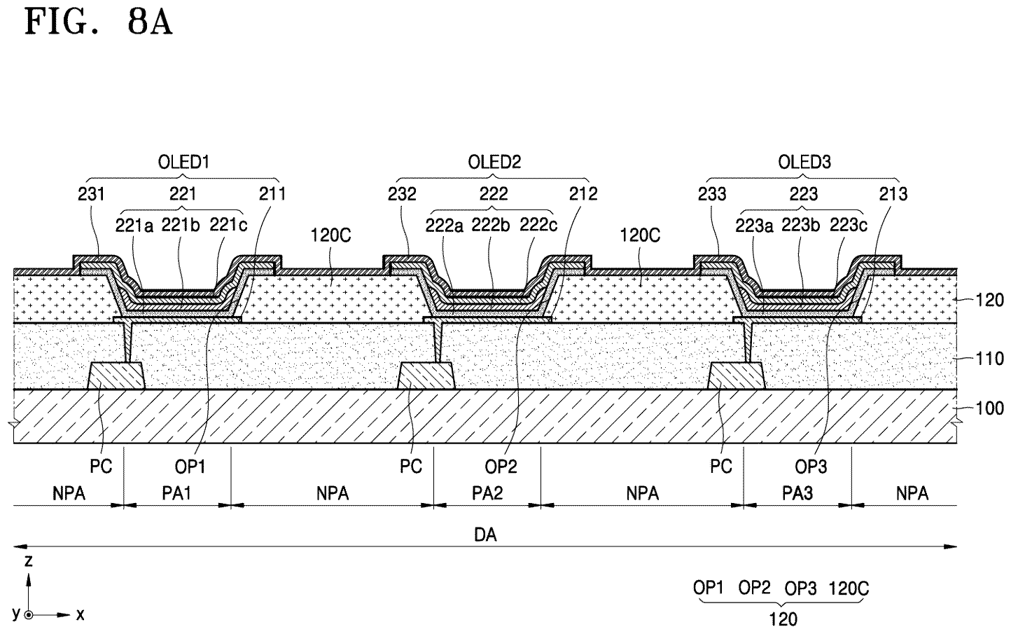

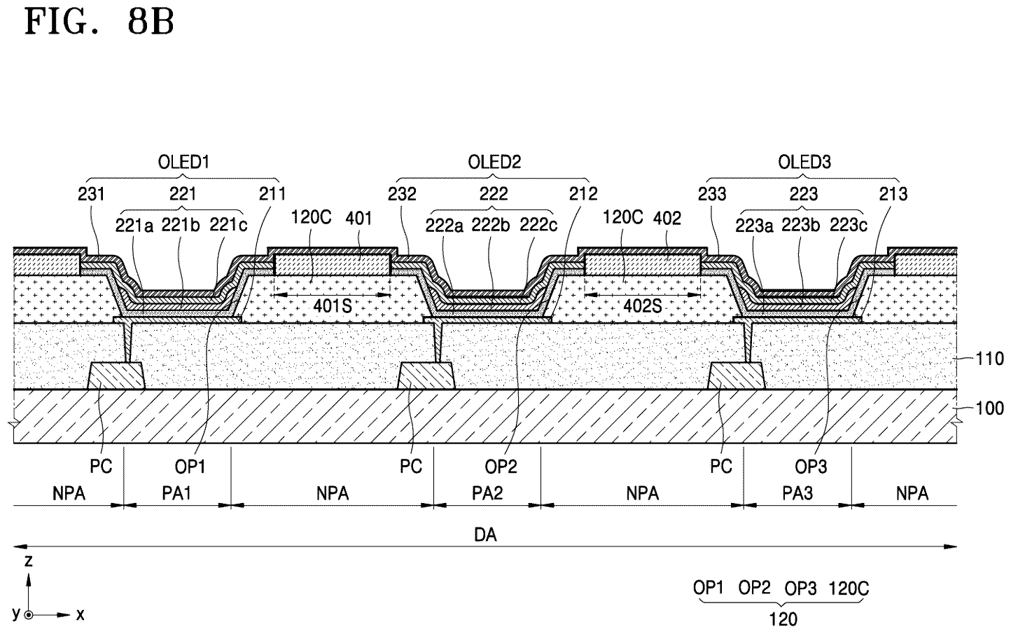

Referring to FIGS. 8A and 8B, at least a portion of the functional layers 220a and 220c located on the cover portion 120c of the pixel definition layer 120 to which the pulse light 600 is radiated may be removed. Therefore, the first lower functional layer 221a and the first upper functional layer 221c may be arranged to correspond to the first opening OP1 of the pixel definition layer 120, and the second lower functional layer 222a and the second upper functional layer 222c may be arranged to correspond to the second opening OP2 of the pixel definition layer 120. In addition, the third lower functional layer 223a and the third upper functional layer 223c may be arranged to correspond to the third opening OP3 of the pixel definition layer 120. After at least a portion of the lower functional layer 220a and the upper functional layer 220c is removed, the counter electrodes 231, 232, and 233 may be arranged continuously on the functional layers 220a and 220c.

The first pixel electrode 211, the first intermediate layer 221, and the first counter electrode 231 may be arranged to correspond to the first opening OP1 of the pixel definition layer 120. The first intermediate layer 221 may include the first lower functional layer 221a, the first emission layer 221b, and the first upper functional layer 221c. The first organic light-emitting device OLED1 including the first pixel electrode 211, the first intermediate layer 221, and the first counter electrode 231 may be located in the first opening OP1 of the pixel definition layer 120. The second pixel electrode 212, the second intermediate layer 222, and the second counter electrode 232 may be arranged to correspond to the second opening OP2 of the pixel definition layer 120. The second intermediate layer 222 may include the second lower functional layer 222a, the second emission layer 222b, and the second upper functional layer 222c. The second organic light-emitting device OLED2 including the second pixel electrode 212, the second intermediate layer 222, and the second counter electrode 232 may be located in the second opening OP2 of the pixel definition layer 120. The third pixel electrode 213, the third intermediate layer 223, and the third counter electrode 233 may be arranged to correspond to the third opening OP3 of the pixel definition layer 120. The third intermediate layer 223 may include the third lower functional layer 223a, the third emission layer 223b, and the third upper functional layer 223C. The third organic light-emitting device OLED3 including the third pixel electrode 213, the third intermediate layer 223, and the third counter electrode 233 may be located in the third opening OP3 of the pixel definition layer 120.

As shown in FIG. 8B, according to some embodiments, the first light absorption layer 401 and the second light absorption layer 402 may be located on the cover portion 120c of the pixel definition layer 120. In detail, the first light absorption layer 401 may be located on the cover portion 120c of the pixel definition layer 120 between the first opening OP1 and the second opening OP2 of the pixel definition layer 120. The second light absorption layer 402 may be located on the cover portion 120c of the pixel definition layer 120 between the second opening OP2 and the third opening OP3 of the pixel definition layer 120.

According to the embodiments as described above, the method of manufacturing the display device having relatively improved efficiency and reliability of manufacturing processes may be implemented. The scope of the disclosure may not be limited by the effect.

While the disclosure has been particularly shown and described with reference to aspects of some embodiments thereof, it will be understood by those of ordinary skill in the art that this is only an example, and various variations and equivalents are made from the disclosure. Therefore, the scope of the disclosure needs to be determined by the technical spirit of the claims.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope as defined by the following claims, and their equivalents.

What is claimed is:

1. A method of manufacturing a display device, the method comprising:
positioning a substrate;
forming a functional layer on the substrate;
forming a mask including an opening in the functional layer;
radiating pulse light including a plurality of pulses through the opening of the mask; and
removing the functional layer to which the pulse light is radiated.

2. The method of claim 1, further comprising:
after the positioning of the substrate, forming a pixel definition layer including plurality of openings in which a pixel electrode is located, on the substrate.

3. The method of claim 2, wherein:
the mask includes a plurality of openings; and
the mask is arranged such that the plurality of openings of the mask are on a region in which the pixel definition layer is located.

4. The method of claim 3, wherein the functional layer to which the pulse light is radiated is at least a portion of a functional layer on the pixel definition layer.

5. The method of claim 2, wherein the forming of the functional layer on the substrate further includes:
forming a lower functional layer on the pixel electrode and the pixel definition layer; and
forming an upper functional layer on the lower functional layer.

6. The method of claim 5, wherein the lower functional layer includes at least one of a hole injection layer or a hole transport layer.

7. The method of claim 5, wherein the upper functional layer includes at least one of an electron injection layer or an electron transport layer.

8. The method of claim 5, further comprising:
between the forming of the lower functional layer and the forming of the upper functional layer, forming an emission layer in an opening of the pixel definition layer.

9. The method of claim 2, wherein a size of the opening of the mask is smaller than a size of a region in which the pixel definition layer is located.

10. The method of claim 1, wherein the pulse light is emitted from a flash lamp.

11. The method of claim 1, wherein the pulse light is light with a wavelength band of ultraviolet, visible, or infrared light.

12. The method of claim 2, further comprising:
forming a light absorption layer on the pixel definition layer.

13. The method of claim 12, wherein the light absorption layer contacts an upper surface of the pixel definition layer.

14. The method of claim 12, wherein a size of the light absorption layer is smaller than a size of a region in which the pixel definition layer is located.

15. The method of claim 12, wherein the light absorption layer includes molybdenum (Mo) or aluminum (Al).

16. The method of claim 1, further comprising:
discharging a residue of a removed portion of the functional layer through openings of a chamber in which the substrate is located.

17. The method of claim 1, further comprising:
forming a transparent deposit prevention plate below the mask.

18. The method of claim 17, further comprising:
collecting and discharging a residue of a removed portion of the functional layer on the transparent deposit prevention plate.

19. A method of manufacturing a display device, the method comprising:
positioning a substrate;
forming a pixel definition layer including an opening in which a pixel electrode is located, on the substrate;
forming a functional layer on the pixel electrode and the pixel definition layer;
forming a mask including an opening such that the opening of the mask is positioned in a region in which the pixel definition layer is located;
radiating light emitted from a flash lamp, through the opening of the mask; and
removing a functional layer on the pixel definition layer to which the light emitted from the flash lamp is radiated.

20. The method of claim 19, further comprising:
forming a light absorption layer to be in contact with an upper surface of the pixel definition layer.
